(19) United States
(12) Patent Application Publication
(10) Pub. No.: US 2016/0211225 A1
(43) Pub. Date: Jul. 21, 2016

(54) SEMICONDUCTOR DEVICE AND MANUFACTURING METHOD THEREOF

(71) Applicant: KABUSHIKI KAISHA TOSHIBA, Tokyo (JP)

(72) Inventors: Shingo MASUKO, Kanazawa Ishikawa (JP); Yoshiharu TAKADA, Nonoichi Ishikawa (JP)

(21) Appl. No.: 14/831,554

(22) Filed: Aug. 20, 2015

(30) Foreign Application Priority Data
Jan. 20, 2015 (JP) 2015-008755

(51) Int. Cl. H01L 23/00; H01L 21/78; H01L 21/308; H01L 29/20; H01L 29/06

(52) U.S. Cl. CPC H01L 23/562; H01L 29/2003; H01L 29/0657; H01L 21/3081; H01L 21/3085; H01L 21/78

(57) ABSTRACT

A semiconductor device includes a substrate, and a nitride semiconductor layer provided on the substrate. An opening is provided through the nitride semiconductor layer, and a portion of the opening extends inwardly of a side surface of the substrate and beneath the nitride semiconductor layer.

### CROSS-REFERENCE TO RELATED APPLICATION

This application is based upon and claims the benefit of priority from Japanese Patent Application No. 2015-008755, filed Jan. 20, 2015, the entire contents of which are incorporated herein by reference.

### FIELD

Embodiments described herein relate generally to a semiconductor device and a manufacturing method thereof, and for example, relate to a semiconductor device including a power semiconductor element and a manufacturing method thereof.

### BACKGROUND

In a power-supply switching circuit, an inverter, or the like, a power semiconductor device including a power semiconductor element such as a switching element or a diode is used. An element using a compound semiconductor such as a nitride semiconductor has excellent material properties, and thus is able to provide a power semiconductor device having high performance.

A semiconductor wafer on which power semiconductor devices are formed is divided into a plurality of semiconductor chips by a dicing step. In this dicing step, chipping or cracking can occur in a nitride semiconductor layer of the device. Chipping is damage which occurs on a dicing surface, and cracking is a flaw which occurs on the dicing surface. Due to chipping or cracking, a defect can occur in the power semiconductor device, and the yield of usable power semiconductor devices recovered from the substrate decreases.

### DESCRIPTION OF THE DRAWINGS

FIG. 1 is a plan view of a semiconductor device according to a first embodiment.

FIG. 2 is a cross-sectional view of a portion of a semiconductor substrate, showing adjacent semiconductor devices according to the first embodiment.

FIGS. 3 to 7 are cross-sectional views illustrating steps in the manufacture of the semiconductor device according to the first embodiment.

FIGS. 8 to 11 are cross-sectional views illustrating steps in the manufacture of a semiconductor device according to a second embodiment.

### DETAILED DESCRIPTION

Embodiments provide a semiconductor device which is able to suppress occurrence of a defect, and a manufacturing method thereof.

In general, according to one embodiment, a semiconductor device includes a substrate and a nitride semiconductor layer provided on the substrate. An opening is provided through the nitride semiconductor layer, and a portion of the opening extends inwardly of a side surface of the substrate and beneath the nitride semiconductor layer.

According to another embodiment, a manufacturing method of a semiconductor device including a first semiconductor chip and a second semiconductor chip which are adjacently disposed includes forming a first mask and a second mask on the first semiconductor chip and the second semiconductor chip, respectively; performing anisotropic etching on a nitride semiconductor layer extending between the first and second semiconductor chips across a gap therebetween; forming a recess in the substrate by isotropically etching into the portion of the substrate which is exposed by the anisotropic etching of the nitride semiconductor layer; and dicing the substrate to separate the first semiconductor chip and the second semiconductor chip along the gap.

Hereinafter, embodiments will be described with reference to the drawings. However, the drawings are schematically or conceptually illustrated, and the dimensions and the scale of the respective drawings are not necessarily identical to the dimension and scale of an actual device. Some embodiments described hereinafter are exemplifications of a device and a method for specifying the technological concept of an exemplary embodiment, and the technological concept of the exemplary embodiment is not specified according to the shape, the structure, the disposition or the like of configurations. Furthermore, in the following description, the same reference numerals are applied to configurations having the same function and the same configuration, and the description thereof will be repeated only when it is necessary.

### First Embodiment

1-1 Configuration of Semiconductor Device

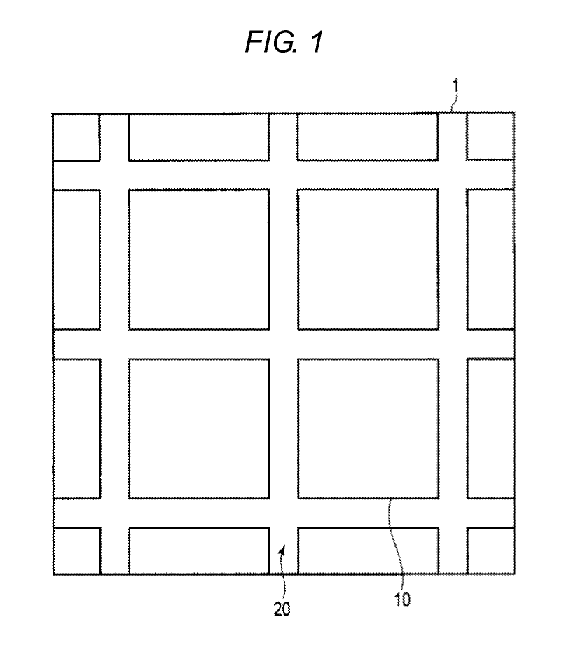

FIG. 1 is a plan view of a semiconductor device 1 according to a first embodiment. The semiconductor device 1 is configured of a semiconductor wafer. FIG. 1 illustrates only a portion of the semiconductor wafer.

The semiconductor device 1, for example, includes a plurality of semiconductor chips 10 which are disposed thereon in a matrix shape or pattern. The plurality of semiconductor chips 10 are disposed with dicing lines 20 extending therebetween. The dicing line 20 is a region for separating the plurality of semiconductor chips 10 by a dicing step, and a nitride semiconductor of the semiconductor chips 10 also extends across the dicing line 20.

Each of the semiconductor chips 10, for example, is configured of a power semiconductor device which performs conversion and control with respect to power-supply (power). As a power semiconductor element included in the power semiconductor device, a power Metal Oxide Semiconductor Field Effect Transistor (MOSFET), a High Electron Mobility Transistor (HEMT), a Heterojunction Bipolar Transistor (HBT), an Insulated Gate Bipolar Transistor (IGBT), a diode, and the like are included.

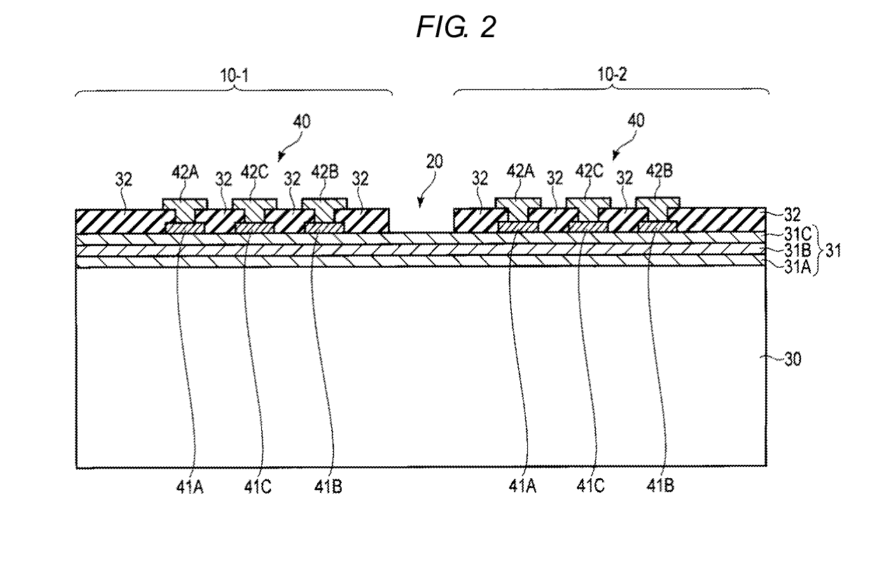

Hereinafter, the semiconductor chip 10 including the HEMT will be described as an example. FIG. 2 is a cross-sectional view of the semiconductor device 1.

The semiconductor device 1 includes semiconductor chips 10-1 and 10-2. The semiconductor chips 10-1 and 10-2 are disposed with the dicing line 20 therebetween. In the following description, when it is not necessary to discriminate between the semiconductor chips 10-1 and 10-2, the reference numeral is shown as the semiconductor chip 10 by omitting the branch number (the numeral after the hyphen), and the description of the semiconductor chip 10 is applied to both of the semiconductor chips 10-1 and 10-2.

The semiconductor chip 10 includes a substrate 30, a nitride semiconductor layer 31, and a protective layer 32. The nitride semiconductor layer 31 is not separately provided in each of the semiconductor chips 10, but is commonly formed for the plurality of semiconductor chips 10. The protective layer 32 is disposed on each of the semiconductor chips 10. That is, a region from which the protective layer 32 has been removed is the dicing line 20. The nitride semiconductor layer 31 corresponding to the dicing line 20 is exposed at the upper surface of the semiconductor device 1.

The substrate 30, for example, is configured of a silicon (Si) substrate having a (111) surface as a main surface. As the substrate 30, silicon carbide (SiC), gallium nitride (GaN), gallium phosphide (GaP), indium phosphide (InP), gallium arsenide (GaAs), sapphire (Al₂O₃), or the like may be used.

The nitride semiconductor layer 31, for example, is configured by laminating three layers of a buffer layer 31A, a channel layer 31B, and a barrier layer 31C one over the other.

The buffer layer 31A is disposed on the substrate 30. The buffer layer 31A has a function of lessening distortion in the device which occurs due to a difference between a lattice constant of the nitride semiconductor layer formed on the buffer layer 31A and a lattice constant of the substrate 30, and also of controlling crystallinity of the nitride semiconductor layer formed on the buffer layer 31A. The buffer layer 31A is, for example, configured of Al_{X}Ga_{1-X}N (0≦X≦1). The buffer layer 31A may be configured by laminating a plurality of Al_{X}Ga_{1-X}N sub-layers having different composition ratios of each constituent. When the buffer layer 31A is configured as a multi-layer stacked structure, a composition ratio of the stacked structure is adjusted such that a lattice constant of a plurality of layers included in the stacked structure is changed from the lattice constant of the lowermost layer among upper and lower layers having the buffer layer 31A interposed therebetween to the lattice constant of an upper layer.

The channel layer 31B is disposed on the buffer layer 31A. The channel layer 31B is a layer on which a channel (a current or carrier path) of a transistor is formed. The channel layer 31B is configured of Al_{X}In_{Y}Ga_{1-(X+Y)}N (0≦X<1, 0≦Y<1, and 0≦X+Y<1). The channel layer 31B is an undoped layer, and is configured of a nitride semiconductor having highly uniform crystallinity (high quality). The term “undoped” indicates that impurities or “dopants” are not intentionally provided therein, and for example, the amount of impurities to the extent of entering in a manufacturing process or the like is in the category of “undoped”. In this embodiment, the channel layer 31B is configured of undoped GaN (referred to as intrinsic GaN).

The barrier layer 31C is disposed on the channel layer 31B. The barrier layer 31C is formed of Al_{X}In_{Y}Ga_{1-(X+Y)}N (0≦X<1, 0Y≦1, and 0≦X+Y<1). The barrier layer 31C is configured of a nitride semiconductor having a bandgap greater than that of the channel layer 31B. In this embodiment, the barrier layer 31C, for example, is configured of undoped AlGaN.

Furthermore, a plurality of semiconductor layers configuring the semiconductor device 1 are, for example, sequentially formed by epitaxial growth using a Metal Organic Chemical Vapor Deposition (MOCVD) method. That is, the plurality of semiconductor layers configuring the semiconductor device 1 are configured as epitaxial layers, which may be form sequentially by changing the ratios of the gas flows into, or other conditions of, the deposition chamber.

The semiconductor chip 10 includes an HEMT 40. The HEMT 40 includes a source electrode 41A, a drain electrode 41B, a gate electrode 41C, and a part of the nitride semiconductor layer 31. Electrode pads 42A, 42B, and 42C are disposed on the source electrode 41A, the drain electrode 41B, and the gate electrode 41C, respectively.

The source electrode 41A and the drain electrode 41B are provided on the barrier layer 31C and are spaced from each other. Further, the gate electrode 41C is provided on the barrier layer 31C and between the source electrode 41A and the drain electrode 41B and spaced from both the source electrode 41A and the drain electrode 41B.

The gate electrode 41C and the barrier layer 31C form a schottky junction. That is, the gate electrode 41C is configured to include a material which forms a schottky junction with the barrier layer 31C. The semiconductor device 1 illustrated in FIG. 2 is a schottky barrier type HEMT. As the gate electrode 41C, for example, a stacked structure of Au/Ni is used. A left side of “/” indicates an upper layer, and a right side thereof indicates a lower layer.

Furthermore, the semiconductor device 1 is not limited to the schottky barrier type HEMT, and may be a Metal Insulator Semiconductor (MIS) type HEMT in which a gate insulating film is interposed between the barrier layer 31C and the gate electrode 41C.

The source electrode 41A and the barrier layer 31C form an ohmic contact with each other. Similarly, the drain electrode 41B and the barrier layer 31C form on ohmic contact with each other. That is, each of the source electrode 41A and the drain electrode 41B are configured to include a material which forms an ohmic contact with the barrier layer 31C. As the source electrode 41A and the drain electrode 41B, for example, a stacked structure of Al/Ti is used.

In a heterojunction structure of the channel layer 31B and the barrier layer 31C, the lattice constant of the barrier layer 31C is smaller than the lattice constant of the channel layer 31B, and thus stress occurs in the barrier layer 31C. A piezoelectric polarization occurs in the barrier layer 31C according to a piezoelectric effect due to the stress, and two-dimensional electron gas (2DEG) is generated in the vicinity of a boundary surface between the channel layer 31B and the barrier layer 31C. The two-dimensional electron gas forms a channel between the source electrode 41A and the drain electrode 41B. Current flowing between the source and drain are controlled by the schottky barrier which occurs due to the junction between the gate electrode 41C and the barrier layer 31C, i.e., by controlling the voltage applied to the gate electrode 41C, the presence or absence of a depletion layer extending across the channel layer can be controlled.

The protective layer 32 is disposed on the nitride semiconductor layer 31 and on portions of the electrodes (including the source electrode 41A, the drain electrode 41B, and the gate electrode 41C). The protective layer 32 is referred to as a passivation layer. The protective layer 32 includes openings therethrough in which electrode pads are formed. The protective layer 32 is configured of an insulating body, and as the protective layer 32, silicon nitride (SiN), silicon oxide (SiO₂), or the like are used.

The electrode pads 42A, 42B, and 42C are used for connection of each of the source, drain and gate electrodes 41A, 41B and 41C to an external circuit, and are exposed to the outside of the semiconductor chip 10. The electrode pads 42A, 42B, and 42C are electrically connected to the source electrode 41A, the drain electrode 41B, and the gate electrode 41C through the opening portions formed in the protective layer 32, respectively.

1-2 Manufacturing Method

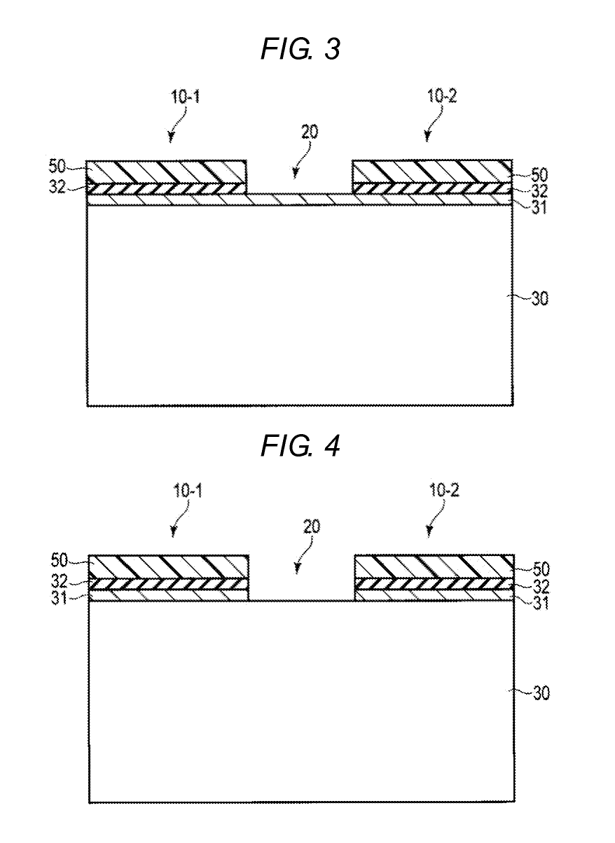

Next, a manufacturing method of the semiconductor device 1 according to the first embodiment will be described with reference to FIG. 3 to FIG. 7. In FIG. 3 to FIG. 7, for the sake of avoiding complexity of the drawings, the nitride semiconductor layer 31 is illustrated as one layer by being simplified, and the electrodes and the electrode pads are not illustrated.

In FIG. 3 to FIG. 7, a portion of the semiconductor device 1 showing one dicing line 20, and two semiconductor chips 10-1 and 10-2 disposed on both sides of the dicing line 20, are illustrated. A width of the dicing line 20 is set based on, and is slightly wider than, the width of a dicing blade used in a dicing step, and for example, is greater than or equal to 45 μm and less than or equal to 70 μm.

First, the semiconductor device (a semiconductor wafer) 1 is prepared in which the plurality of semiconductor chips 10 is formed on the substrate 30. Subsequently, a back surface of the substrate 30 is removed using a grinding or polishing device, and thus the substrate 30 is thinned to a predetermined thickness. The thickness of the substrate 30 is suitably selected according to the specification of the semiconductor chip 10.

Subsequently, as illustrated in FIG. 3, a resist (a mask layer) 50 is formed on the semiconductor chips 10-1 and 10-2 (specifically, the protective layer 32) using a photolithography method. In other words, a patterned resist 50 is formed in a region other than the dicing line 20.

Subsequently, as illustrated in FIG. 4, the nitride semiconductor layer 31 is subjected to anisotropic etching by using the resist 50 as a mask. In the anisotropic etching step, for example, a Reactive Ion Etching (RIE) method is used. The nitride semiconductor layer 31 in a region corresponding to the dicing line 20 is removed by the anisotropic etching step.

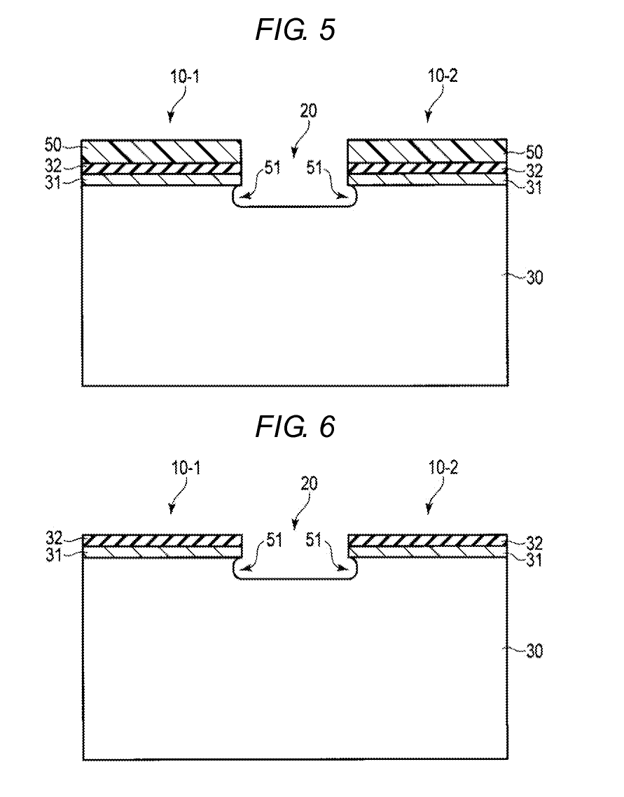

Subsequently, as illustrated in FIG. 5, the substrate 30 is partially subjected to isotropic etching while continuing to use the resist 50 as a mask. The etchant selected is selective to preferentially etch the underlying substrate material, for example silicon, as compared to the nitride semiconductor material. An etching amount (an etching depth and expanded width) according to the isotropic etching step, for example, is approximately 5 μm. In the isotropic etching step, for example, isotropic plasma etching or wet etching is used.

As illustrated in FIG. 5, sideways, i.e., lateral, etching of the substrate 30 occurs during the isotropic etching step to etch a recess or concave feature 51 into the substrate below the nitride semiconductor layer at the side thereof. The concave feature 51 is thus formed in the substrate 30 in a region corresponding to an end of the nitride semiconductor layer 31 by the isotropic etching step. The concave feature 51 intrudes beneath the nitride semiconductor layer 31. In other words, an undercut is formed beneath the nitride semiconductor layer 31. An end of the concave feature 51 in an in-plane direction of the upper surface of the substrate 30 is positioned inwardly of the semiconductor chip 10 from the side of the nitride semiconductor layer 31. Subsequently, as illustrated in FIG. 6, the resist 50 is removed.

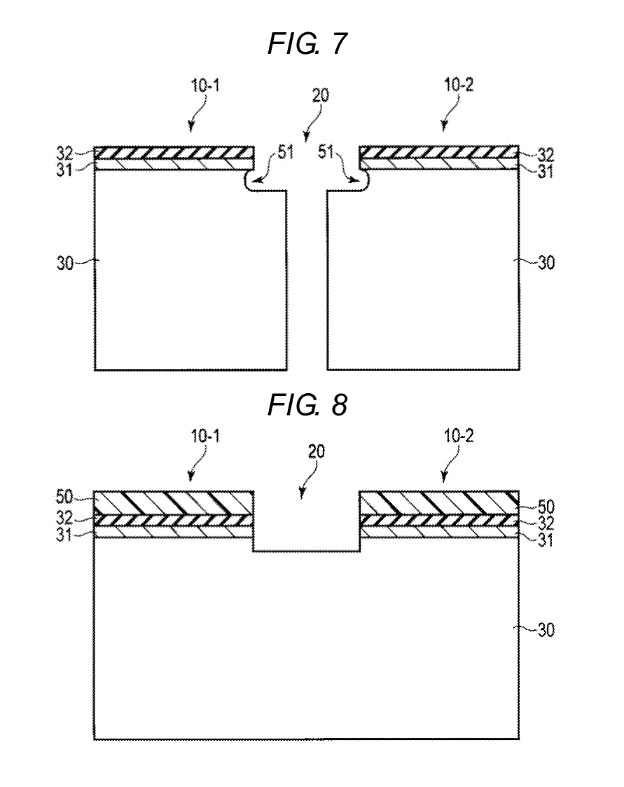

As illustrated in FIG. 7, the semiconductor device 1 is then diced along the dicing line 20, and the semiconductor device 1 is divided into the plurality of semiconductor chips 10. In the dicing step, blade dicing, laser dicing, or the like is used. In this embodiment, the nitride semiconductor layer 31 was subjected to anisotropic etching, and thus a side surface of the nitride semiconductor layer 31 is extends outwardly from the side surface of the substrate 30 in the in-plane direction over the recess.

In the dicing step, chipping or a crack may occur in a cut surface of the substrate 30. An edge of the semiconductor chip 10 is cracked or chipped due to this chipping. Further, the chipping or cracking of the substrate 30 may extend to the nitride semiconductor layer 31, and thus chipping or a crack occurs in the nitride semiconductor layer 31. However, in this embodiment, as illustrated in FIG. 7, the concave feature 51 is formed in the side surface of the isotropically etched portion of the substrate 30 and extends beneath the nitride semiconductor layer 31. Accordingly, even when chipping occurring during dicing reaches to the concave feature 51, is possible to prevent the chipping of the substrate 30 from reaching the nitride semiconductor layer 31, because a crack or chip generated during cutting will likely extend to the recess below the nitride semiconductor layer, and thus terminate there.

1-3 Effect of First Embodiment

As described above, in the first embodiment, the portion of the nitride semiconductor layer 31 adjacent to the dicing line (a gap) 20 is removed by the anisotropic etching, and then the portion of the substrate 30 exposed by the anisotropic etching is subjected to isotropic etching by a predetermined etching amount. The resulting concave feature 51 which extends beneath the nitride semiconductor layer 31 is formed on the substrate 30 by the isotropic etching step. After that, the semiconductor device 1 is diced along the dicing line 20.

Therefore, according to the first embodiment, even when chipping or a crack occurs in the side surface of the substrate 30 and in the vicinity of the concave feature 51, the concave feature 51 of the substrate 30 will prevent the chipping of the substrate 30 from extending into the overlying nitride semiconductor layer 31, and thus it is possible to prevent the chipping from occurring in the nitride semiconductor layer 31.

As a result thereof, it is possible to prevent a defect from occurring in the semiconductor chip 10. In addition, it is possible to prevent the yield of useful devices from the substrate from decreasing.

### Second Embodiment

In a second embodiment, the substrate 30 is overetched by the anisotropic etching after the nitride semiconductor layer 31 is etched through in the anisotropic etching process, to form an anisotropically formed recess into the substrate 30. After that, the substrate 30 is subjected to isotropic etching, and thus the concave feature 51 is formed in the substrate at the location below the nitride semiconductor layer 31.

Hereinafter, a manufacturing method of the semiconductor device 1 according to a second embodiment will be described with reference to FIG. 8 to FIG. 11. Manufacturing steps up to FIG. 3 are the same as that of the first embodiment.

Subsequently, as illustrated in FIG. 8, the nitride semiconductor layer 31 is subjected to anisotropic etching using the resist 50 as a mask. Subsequently, the exposed portions of the substrate 30 are subjected to anisotropic etching using the resist 50 as a mask. The nitride semiconductor layer 31 in the region corresponding to the dicing line 20 is removed by the anisotropic etching step, and an opening portion having a width substantially the same as that of the dicing line 20 is formed inwardly of the substrate 30.

The anisotropic etching of the substrate 30 may be continuously performed after etching through of the nitride semiconductor layer 31 by changing the type of gas from that useful for etching the nitride semiconductor layer 31 to that useful for etching the substrate 30 material. Alternatively, the anisotropic etching step of the substrate 30 may be performed by the overetching of the nitride semiconductor layer 31 using the same type of gas. An etching amount (opening depth)of the substrate 30 according to the anisotropic etching is, for example, approximately 10 μm. In the anisotropic etching step, for example, an RIE method is used.

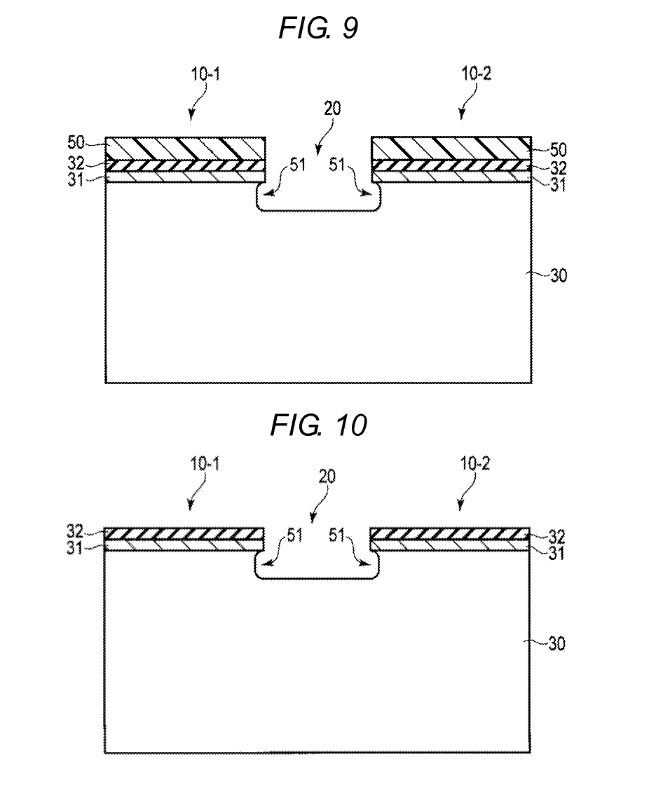

Subsequently, as illustrated in FIG. 9, the substrate 30 is partially subjected to the isotropic etching by using the resist 50 as a mask. An etching amount according to the isotropic etching step, for example, is approximately 5 μm. In the isotropic etching step, for example, isotropic plasma etching or wet etching is used.

As illustrated in FIG. 9, side etching of the substrate 30 occurs due to the isotropic etching step with an etchant that is selective to etch silicon over the material of the nitride semiconductor layer. The concave feature 51 or recess is formed in the substrate 30 below the end of the nitride semiconductor layer 31 by the isotropic etching step. The concave feature 51 intrudes beneath the nitride semiconductor layer 31. The end of the concave feature 51 in the in-plane direction is positioned on the inner side of the semiconductor chip 10 from the end of the nitride semiconductor layer 31.

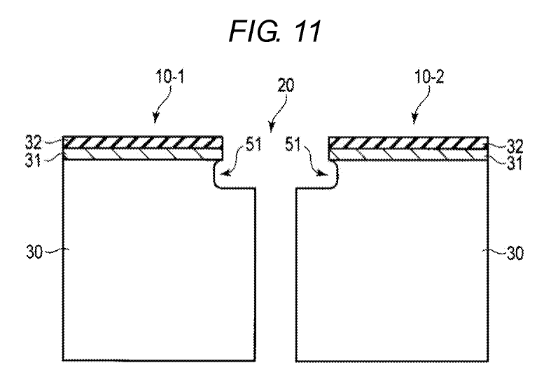

Subsequently, as illustrated in FIG. 10, the resist 50 is removed. Subsequently, as illustrated in FIG. 11, the semiconductor device 1 is diced along the dicing line 20, and the semiconductor device 1 is divided into the plurality of semiconductor chips 10. In the dicing step, blade dicing, laser dicing, or the like is used.

As described above, similar to the first embodiment, in the second embodiment, the concave feature 51 is formed in the substrate 30 corresponding to the end of the nitride semiconductor layer 31. Accordingly, the same effect as that of the first embodiment is able to be obtained.

In addition, in the second embodiment, the substrate 30 is subjected to anisotropic etching, and an opening is formed in the substrate 30, and then the substrate 30 is partially subjected to isotropic etching within the opening to form the concave feature 51 extending under the nitride layer 31. Accordingly, it is possible to make the shape of the side surface of the concave feature 51 more smooth, and thus it is possible to form the concave feature 51 having a desired shape. Specifically, it is possible to control the amount (sideways extension) of the concave feature 51 which extends beneath the nitride semiconductor layer 31.

Furthermore, in the respective embodiments, the semiconductor device is used in which the nitride semiconductor layer is formed on the substrate. However, the semiconductor device is not limited thereto, and the respective embodiments are able to be applied to a semiconductor device in which an epitaxial layer formed of a compound semiconductor of which a material is different from that of the substrate is formed on the substrate.

Herein, “stack” includes a case of overlapping by including another layer therebetween in addition to a case of overlapping in contact with each other. In addition, “provided on” includes a case of being provided by including another layer therebetween in addition to a case of being provided in directly contact with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate; and
a nitride semiconductor layer provided on the substrate,
wherein an opening is provided through the nitride semiconductor layer, and
a portion of the opening extends inwardly of a side surface of the substrate and beneath the nitride semiconductor layer.

2. The device according to claim 1, wherein the opening extends in an in-plane direction of the substrate.

3. The device according to claim 1, wherein a side surface of the nitride semiconductor layer is positioned outwardly of the adjacent side surface of the substrate in the in-plane direction of the substrate.

4. The device according to claim 1, wherein the nitride semiconductor layer comprises gallium nitride (GaN).

5. The device according to claim 1, wherein the substrate comprises silicon (Si).

6. The device according to claim 1, further comprising a gap between the underside of the nitride semiconductor layer and the surface of the substrate directly facing the nitride semiconductor layer at a portion of the nitride semiconductor layer extending inwardly of a side of the device.

7. The device according to claim 1, further comprising a crack extending from the side surface of the semiconductor substrate and terminating in the portion of the opening extending inwardly of the side surface of the substrate.

8. The device according to claim 1, wherein the side surface of the semiconductor substrate is chipped, and at least a portion of the opening extending inwardly of the side surface of the substrate remains between the nitride semiconductor layer and the facing surface of the substrate.

9. A method of forming a first semiconductor chip and a second semiconductor chip disposed on a substrate with a gap therebetween, the method comprising:
forming a first mask and a second mask on the first semiconductor chip and the second semiconductor chip, respectively;
performing anisotropic etching through a nitride semiconductor layer located in the gap;
forming a concave feature by isotropic etching into a substrate exposed by the anisotropic etching to etch into the substrate and etch away a portion of the substrate below the side surface of the nitride semiconductor layer to form a recess extending inwardly of the substrate adjacent to a side surface of the nitride semiconductor layer; and
dicing the first semiconductor chip and the second semiconductor chip along the gap.

10. The method of claim 9, wherein the nitride semiconductor layer in the gap extends inwardly of the first semiconductor chip and the second semiconductor chip and forms the device region thereof.

11. The method of claim 9, further comprising:
forming a sidewall of the semiconductor substrate of the first semiconductor chip by dicing the first semiconductor chip and the second semiconductor chip along the gap and simultaneously forming a crack in the sidewall of the semiconductor substrate of the first semiconductor chip; and
terminating the crack in the recess extending below the nitride semiconductor layer.

12. The method of claim 9, further comprising:
forming a sidewall of the semiconductor substrate of the first semiconductor chip by dicing the first semiconductor chip and the second semiconductor chip along the gap and simultaneously removing a portion of the sidewall as a chip in the sidewall of the semiconductor substrate of the first semiconductor chip,
wherein a portion of the recess of the concave feature extending below the nitride semiconductor layer remains adjacent to the location of the sidewall where the chip was removed.

13. The method of claim 9, wherein the dicing is performed with a cutting blade having a width smaller than the width of the gap.

14. A method of manufacturing a semiconductor device including a first semiconductor chip and a second semiconductor chip that are provided on a substrate with a gap therebetween, the method comprising:
forming a first mask and a second mask on the first semiconductor chip and the second semiconductor chip, respectively;
performing anisotropic etching through a nitride semiconductor layer provided in the gap;
performing anisotropic etching into a substrate exposed by the anisotropic etching of the nitride semiconductor layer;
forming a concave feature by partially performing isotropic etching into the substrate after the anisotropic etching into the substrate; and
dicing the first semiconductor chip and the second semiconductor chip along the gap.

15. The method according to claim 14, wherein the nitride semiconductor layer comprises gallium nitride (GaN).

16. The method according to claims 14, wherein the substrate comprises silicon (Si).

17. The method according to claim 14, wherein a recess is etched between the nitride semiconductor layer and the substrate during the isotropic etching.

18. The method according to claim 14, wherein the anisotropic etching is reactive ion etching.

19. The method according to claim 18 wherein, during the anisotropic etching through the nitride semiconductor layer and into the substrate, a gas species of a plasma used in the anisotropic etching is changed.

20. The method according to claim 14, wherein the isotropic etching is performed by wet etching.
